(19) United States
(12) Patent Application Publication
(10) Pub. No.: US 2012/0228646 A1
(43) Pub. Date: Sep. 13, 2012

(54) LIGHT EMITTING DIODE PACKAGE AND METHOD FOR MAKING THE SAME

(75) Inventors: TE-WEN KUO, Hsinchu (TW); YU-FEN CHANG, Hukou (TW); WEN-LIANG TSENG, Hukou (TW)

(73) Assignee: ADVANCED OPTOELECTRONIC TECHNOLOGY, INC., Hsinchu Hsien (TW)

(21) Appl. No.: 13/304,701

(22) Filed: Nov. 28, 2011

(30) Foreign Application Priority Data
Mar. 7, 2011 (CN) 201110053122.3

(51) Int. Cl. H01L 33/50; H01L 33/52

(52) U.S. Cl. 257/88; 438/27; 257/E33.068; 257/E33.061

(57) ABSTRACT

An LED package includes a substrate; a plurality of LED units formed on the substrate; and a phosphor tape arranged on the LED units. Light from the LED units travels to an external environment through the phosphor tape. The phosphor tape has phosphor particles evenly distributed therein. A method for forming the LED package is also provided.

### 1. TECHNICAL FIELD

The disclosure generally relates to a light emitting diode package and method for making the same.

### 2. DESCRIPTION OF RELATED ART

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In the package of LED units, phosphor particles are generally doped into the encapsulation material, and then the encapsulation material is disposed on the LED units. However, because a density of the phosphor particles is greater than that of the encapsulation material, the phosphor particles will gradually deposit to a bottom of the encapsulation material. An uneven distribution of the phosphor particles in the encapsulation will affect lighting properties of the LED package.

Therefore, an LED package is desired to overcome the above described shortcoming.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 shows an LED package in accordance with a first embodiment of the present disclosure.

FIG. 2 is a cross-sectional view of a substrate and LED units formed on the substrate for constructing the LED package of FIG. 1.

FIG. 3 shows a step for applying a phosphor tape on the substrate of FIG. 2.

FIG. 4 is an enlarged view of the phosphor tape of FIG. 3.

FIG. 5 shows an LED package in accordance with a second embodiment of the present disclosure.

FIG. 6 is a cross-sectional view of a substrate and LED units formed on the substrate for constructing the LED package of FIG. 5.

FIG. 7 shows a step for forming a transparent encapsulation layer on the substrate of FIG. 6.

FIG. 8 shows a step for applying a first phosphor tape on the transparent encapsulation layer of FIG. 7.

FIG. 9 shows a step for applying a second phosphor tape on the transparent encapsulation layer of FIG. 8, wherein FIG. 9 is viewed from a top of FIG. 8.

FIG. 10 shows an LED package in accordance with a third embodiment of the present disclosure.

FIG. 11 a cross-sectional view of a substrate and a reflective cup formed on the substrate for constructing the LED package of FIG. 10.

FIG. 12 shows a step for mounting LED units on the substrate and inside the reflective cup of FIG. 11.

FIG. 13 shows a step for forming a transparent encapsulation layer on the substrate and inside the reflective cup of FIG. 11.

FIG. 14 shows a step for applying a phosphor tape on the transparent encapsulation layer of FIG. 13.

### DETAILED DESCRIPTION

Embodiments of LED packages will now be described in detail below and with reference to the drawings.

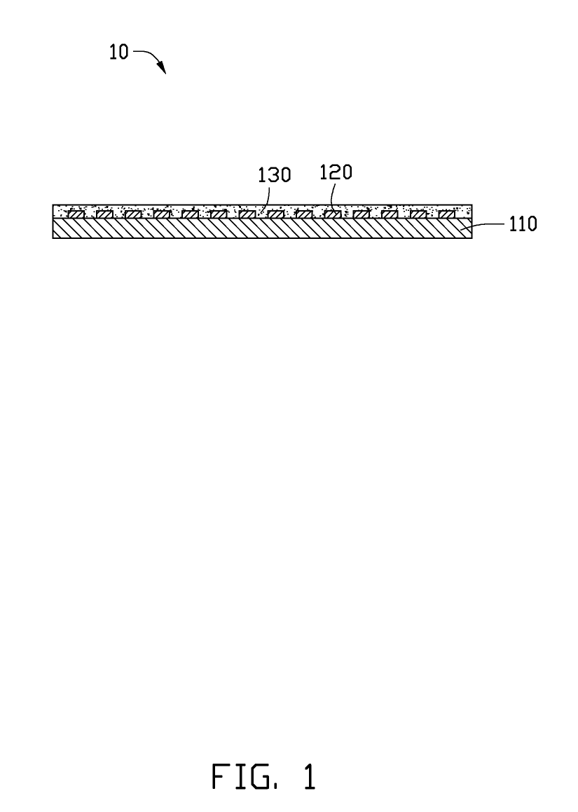

Referring to FIG. 1, an LED package 10 according to a first embodiment is provided. The LED package 10 includes a substrate 110, LED units 120 arranged on the substrate 110 and a phosphor tape 130 formed a top surface of the substrate 110 and encapsulating the LED units 120 therein. Light emitting surfaces of the LED units 120 are top surfaces thereof, which face a top surface of the phosphor tape 130.

The substrate 110 is elongated, which can be made of Si, Al, Al₂O₃, SiC. In this embodiment, the substrate 110 is an Al-based printed circuit board, to effectively transfer heat generated by the LED units 120 to an outer environment. Conductive traces (not shown) are formed on a top surface of the substrate 110 to electrically connect with the LED units 120 whereby the LED units 120 can conveniently connect with an external power source (not shown).

The LED units 120 are arranged along a lengthwise direction of the substrate 110. The LED units 120 form a series connection or a parallel connection with each other. In this embodiment, materials of the LED units 120 can be selected from a group consisting of GaN, AlGaN, InGaN and AlInGaN.

The phosphor tape 130 is attached to the substrate 110 and totally covers the LED units 120. Light from the LED units 120 travels to the external environment through the phosphor tape 130. The phosphor tape 130 absorbs part of the light emitted by the LED units 120 with a first wavelength, and emits light with a second wavelength. The other part of light emitted from the LED units 120 and the light emitted from the phosphor tape 130 mix together to form white light.

The LED package 10 is obtained by following steps:

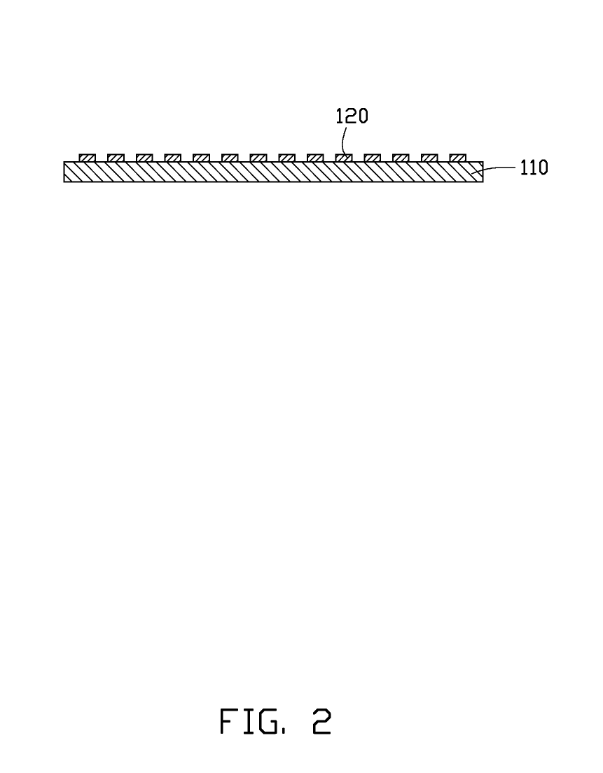

Referring to FIG. 2, a substrate 110 is firstly provided. The substrate 110 is an elongated printed circuit board, which can be made of Si, Al, Al₂O₃, or SiC. LED units 120 are mounted on a top surface of the substrate 110 and arranged along a lengthwise direction of the substrate 110.

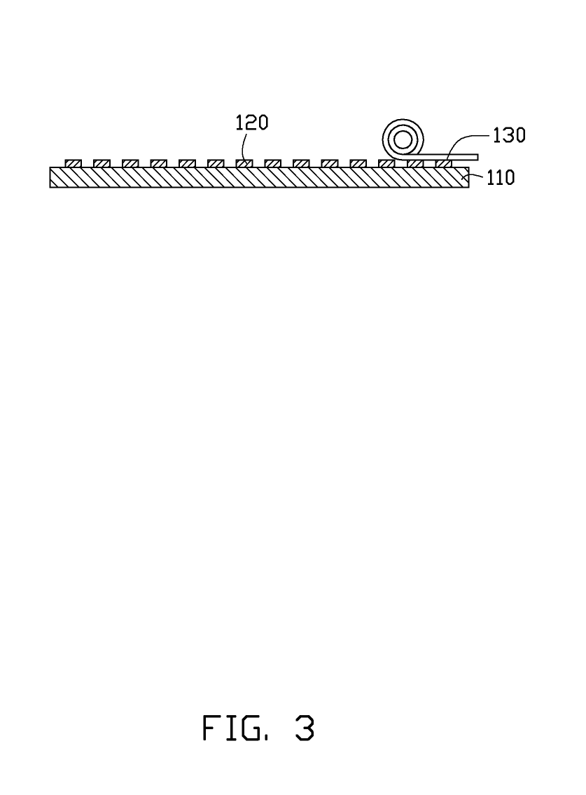

Referring to FIG. 3, a phosphor tape 130 is provided. Then, the phosphor tape 130 is attached to the substrate 110 to totally cover the LED units 120, thereby forming an LED package 10 as shown in FIG. 1.

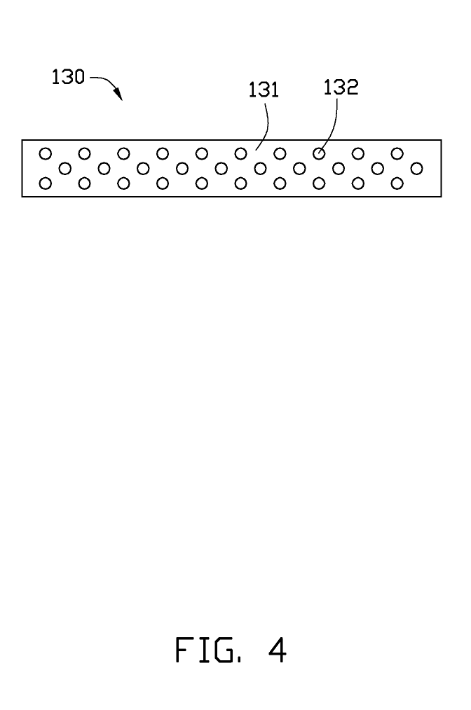

Referring to FIG. 4, the phosphor tape 130 includes a transparent carrier 131 and phosphor particles 132 evenly distributed within the transparent carrier 131. Materials of the transparent carrier 131 can be silica gel, polyethylene, polypropylene, polyvinyl chloride or polycarbonate. Materials of the phosphor particles 132 can be yttrium aluminum garnet, nitride, phosphide, sulfide or silicate compounds. The phosphor tape 130 is formed by coating, screen printing or tape casting. In this embodiment, the phosphor tape 130 can be formed by following steps: forming a mixture of phosphor particles 132, transparent carriers 131 and an organic solvent; providing a glass substrate and coating the mixture on the glass substrate; heating the mixture to evaporate the organic solvent and form a phosphor tape 130 with a predetermined thickness; peeling off the phosphor tape 130 from the glass substrate and rolling the phosphor tape 130 into a roll. Therefore, the roll-shaped phosphor tape 130 can be used in a later stage for packaging of the LED units 120.

In the LED package 10 described above, the phosphor tape 130 is provided in advance; therefore the thickness, the shape and the density of phosphor particles 132 in the phosphor tape 130 can be easily controlled. Therefore, a uniform light distribution of the LED package 10 is provided and the manufacture process of the phosphor tape 130 becomes simple. Moreover the deposition of the particles 132 in the bottom of the phosphor 130 is avoided since the phosphor tape 130 is quickly cured by heating the mixture to evaporate the organic solvent.

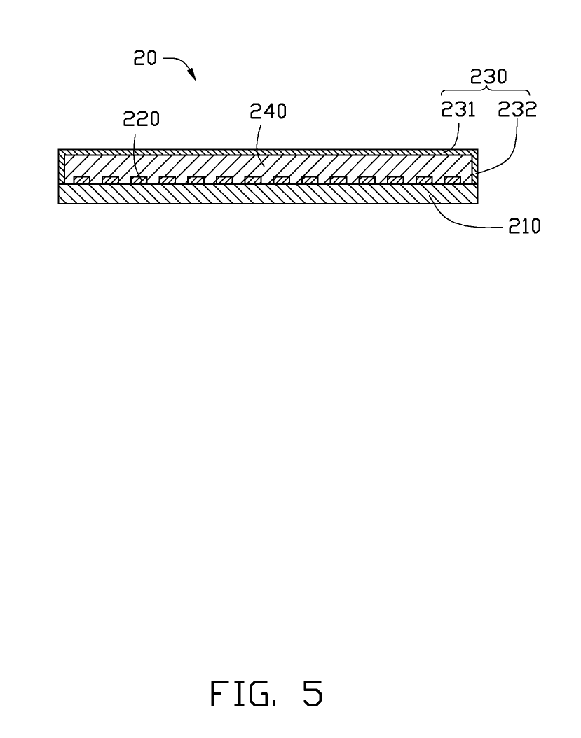

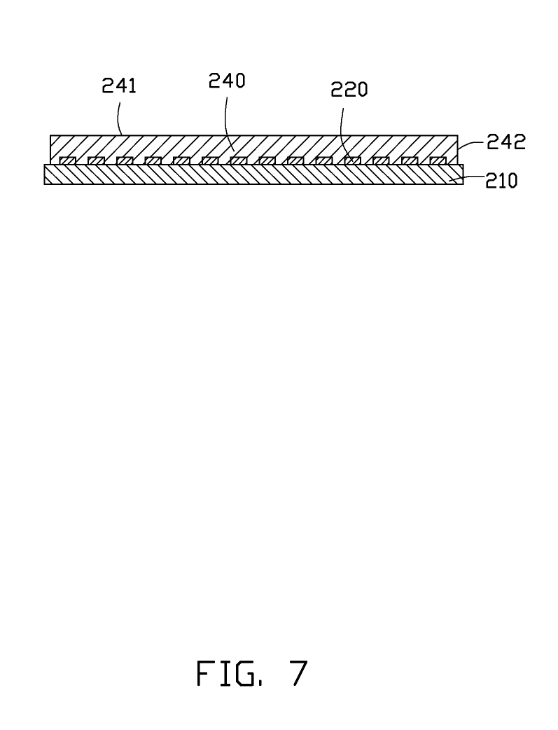

Referring to FIG. 5, an LED package 20 according to a second embodiment is provided. The LED package 20 includes a substrate 210, LED units 220 arranged on the substrate 210 and a phosphor tape 230 formed on the top surface of the substrate 210 and encapsulating the LED units 220 therein. Different from the first embodiment, a transparent encapsulation layer 240 is formed between the LED units 220 and the phosphor tape 230. The transparent encapsulation layer 240 totally covers the LED units 220 to prevent the LED units 220 from being affected by dust or moisture. In this embodiment, the transparent encapsulation layer 240 has a top surface 241 (FIG. 7) over the LED units 220 and a side surface 242 interconnecting the top surface 241 and the substrate 210 and surrounding the LED units 220. The phosphor tape 230 includes a first phosphor tape 231 and a second phosphor tape 232. The first phosphor tape 231 is attached to the top surface 241 of the transparent encapsulation layer 240, and the second phosphor tape 232 is attached to the side surface 242 of the transparent encapsulation layer 240. Light from the LED units 220 travels to the external environment through the transparent encapsulation layer 240 and the phosphor tape 230.

The LED package 20 is manufactured by following steps:

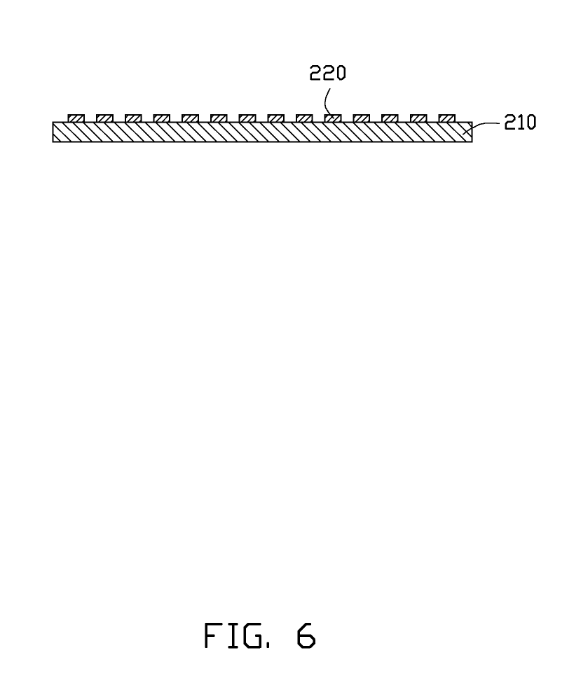

Referring to FIG. 6, firstly, similar to the first embodiment, a substrate 210 is provided with LED units 220 arranged thereon.

Referring to FIG. 7, a transparent encapsulation layer 240 is formed on the substrate 210 to cover the LED units 220. In this embodiment, the transparent encapsulation layer 240 is a rectangular parallelepiped structure. Materials of the transparent encapsulation layer 240 can be selected from a group consisting of epoxy resin, silicate gel and polycarbonate.

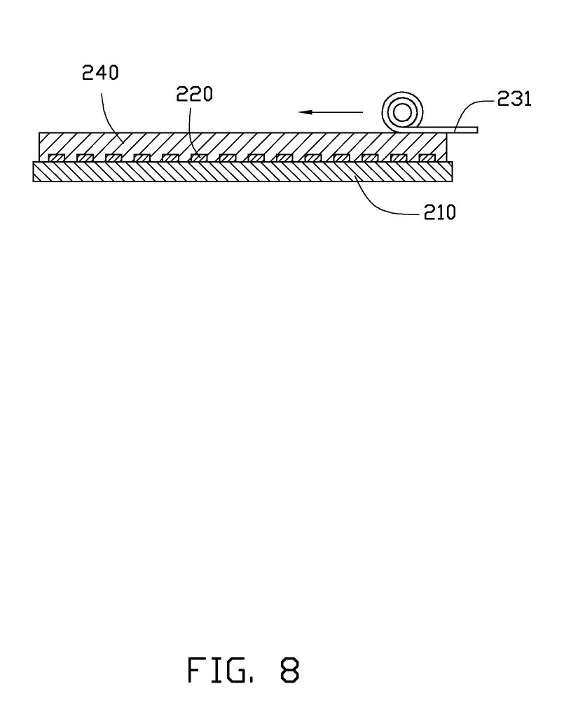

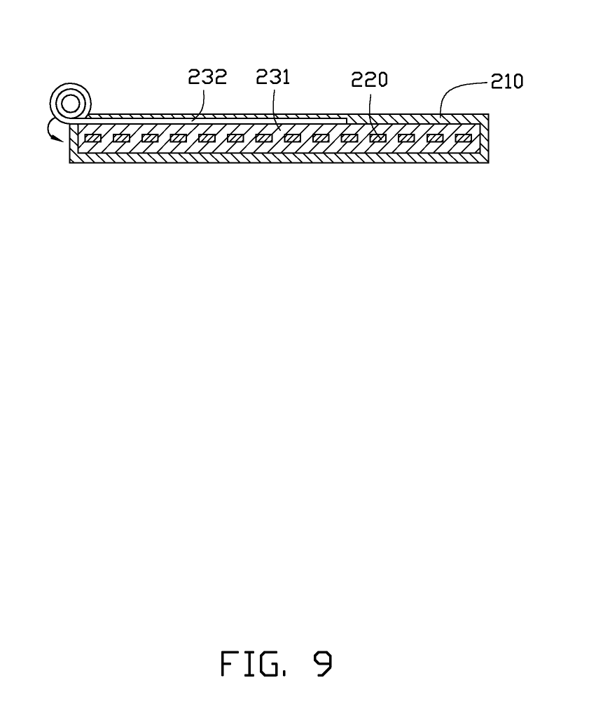

Referring to FIG. 8-9, a first phosphor tape 231 is applied to the top surface 241 of the transparent encapsulation layer 240, and a second phosphor tape 232 is attached to the side surface 242 of the transparent encapsulation layer 240. The first phosphor tape 231 and the second phosphor tape 232 are formed by a method the same as that for forming the phosphor tape 130 of the first embodiment. The application of the first phosphor tape 231 and the second phosphor tape 232 to the transparent encapsulation layer 242 is processed before the transparent encapsulation layer 240 is solidified. After the phosphor tape 230 consisting of the first and second phosphor tapes 231, 232 is attached to the transparent encapsulation layer 240, the transparent encapsulation layer 240 is heated and cured to obtain a firm connection of the transparent encapsulation layer 240 and the phosphor tape 230.

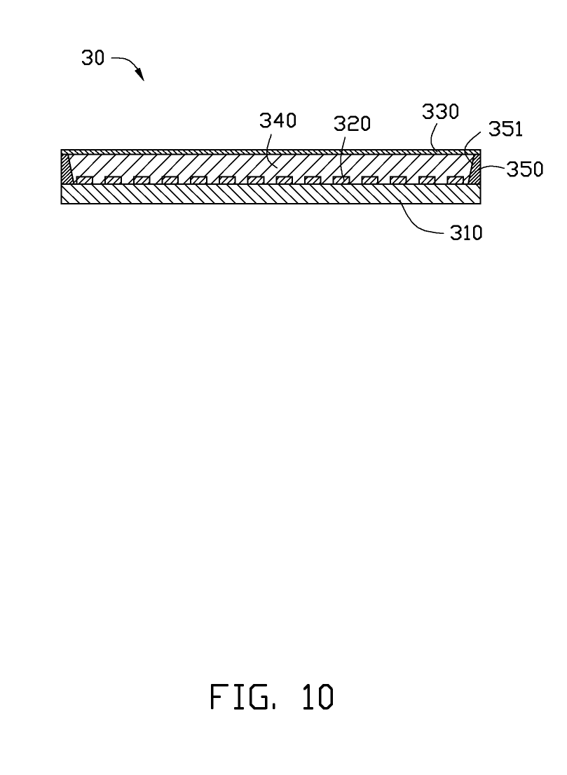

Referring to FIG. 10, an LED package 30 according to a third embodiment is provided. The LED package 30 includes a substrate 310, LED units 320 formed on the substrate 310, a transparent encapsulation layer 340 sealing the LED units 320 therein and a phosphor tape 330 covering the transparent encapsulation layer 340. Light from the LED units 320 travels to the external environment through the transparent encapsulation layer 340 and the phosphor tape 330. Different from the second embodiment, a reflective cup 350 is formed on the substrate 310. A receiving chamber 351 is defined at a central of the reflective cup 350, and the LED units 320 are received in the receiving chamber 351. By filling encapsulation material in the receiving chamber 351, a transparent encapsulation layer 340 is formed in the reflective cup 350 to cover the LED units 320. In addition, a metal reflective layer can be further formed on an inner sidewall of the reflective cup 350 to enhance the reflectivity of the reflective cup 350.

The LED package 30 is fabricated by following steps:

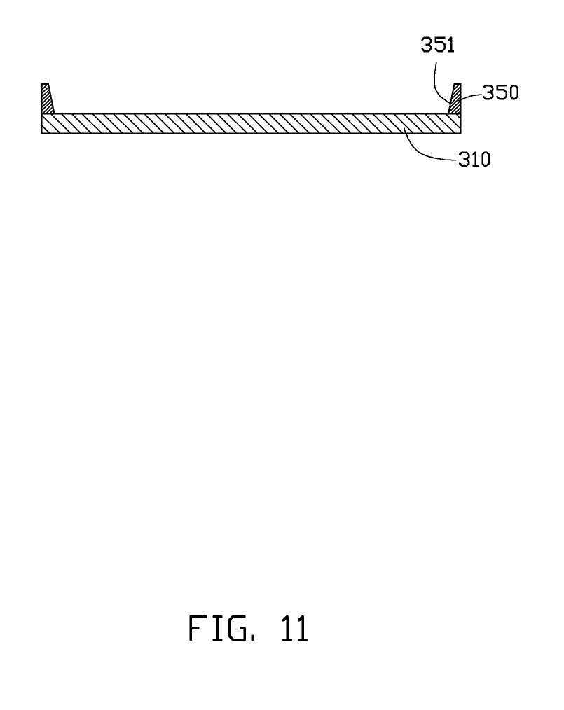

Referring to FIG. 11, a substrate 310 is first provided. The substrate 310 is elongated and a reflective cup 350 is formed on the substrate 310. A receiving chamber 351 is formed inside the reflective cup 350.

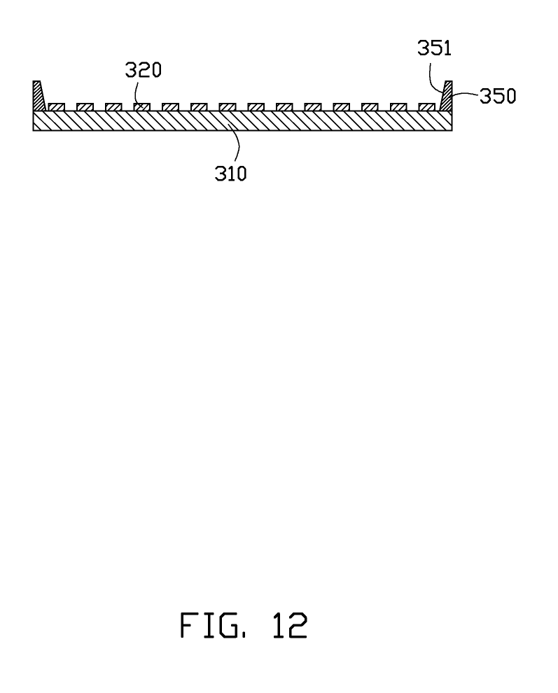

Referring FIG. 12, the LED units 320 are arranged on the substrate 310 and in the receiving chamber 351.

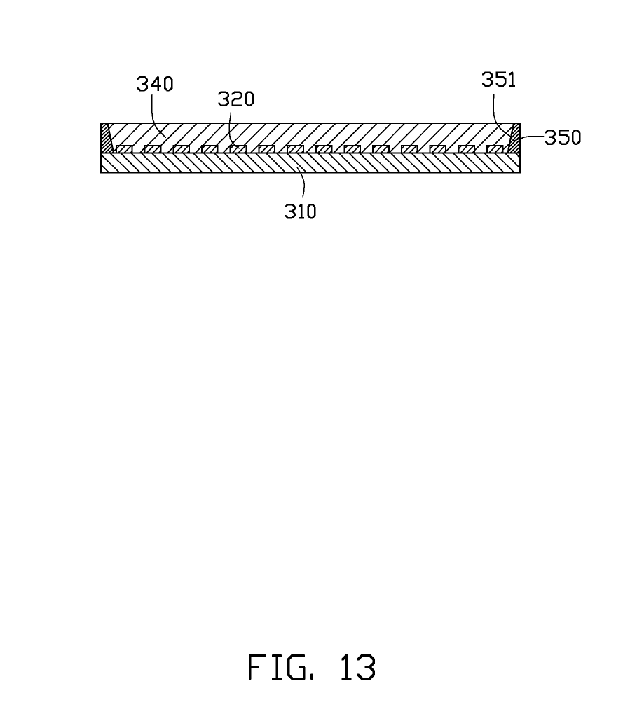

Referring to FIG. 13, the transparent encapsulation layer 340 is formed in the receiving chamber 351 to totally cover the LED units 320. Therefore, the LED units 320 are prevented from being affected by external matters such as dust and moisture. Materials of the transparent encapsulation layer 340 can be selected from a group consisting of epoxy resin, silicate gel and polycarbonate.

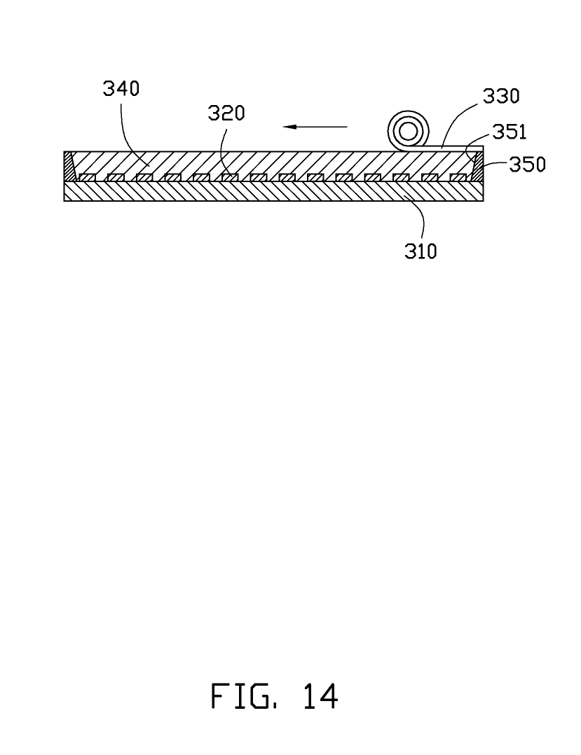

Referring to FIG. 14, a phosphor tape 330 is provided, and attached to a top surface of the transparent encapsulation layer 340, thereby forming an LED package 30 as shown in FIG. 10. The attachment of the transparent encapsulation layer 340 is processed before the transparent encapsulation layer 340 is cured. After the phosphor tape 330 is attached to the transparent encapsulation layer 340, the phosphor tape 330 is heated and cured to firmly connect with the transparent encapsulation layer 340. In another embodiment, the LED package 30 can also have the phosphor tape 330 directly applied to a top the reflective cup 350. In such an embodiment, the receiving chamber 351 is filled with air and the encapsulation material 340 is omitted.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting diode package, comprising:
a substrate;
a plurality of LED units formed on the substrate; and
a phosphor tape arranged on the LED units, the phosphor tape having phosphor particles evenly distributed therein, light from the LED units travelling to an external environment through the phosphor tape.

2. The light emitting diode package of claim 1, wherein the phosphor tape comprises a transparent carrier and the phosphor particles, and the phosphor particles are evenly distributed in the transparent carrier.

3. The light emitting diode package of claim 2, wherein a material of the transparent carrier is selected from a group consisting of silica gel, polyethylene, polypropylene, polyvinyl chloride and polycarbonate.

4. The light emitting diode package of claim 2, wherein a material of the phosphor particles is selected from a group consisting of yttrium aluminum garnet, nitride, phosphide, sulfide and silicate compounds.

5. The light emitting diode package of claim 1, further comprising a transparent encapsulation layer formed between the phosphor tape and the LED units.

6. The light emitting diode package of claim 1, further comprising a reflective cup, wherein the reflective cup receives the LED units therein.

7. The light emitting diode package of claim 1, wherein the phosphor tape is directly attached to the substrate and totally covers the LED units.

8. A method for forming a light emitting diode package, comprising steps:
providing a substrate with a plurality of LED units arranged thereon;
providing a phosphor tape including phosphor particles evenly distributed therein; and
attaching the phosphor tape to the substrate in which the phosphor tape covers the LED units.

9. The method of claim 8, further comprising forming a transparent encapsulation layer on the substrate in which the LED units are covered by the transparent encapsulation layer before attaching the phosphor tape to the substrate, the phosphor tape being attached on the transparent encapsulation layer.

10. The method of claim 9, wherein the attachment of the phosphor tape to the transparent encapsulation layer is processed before the transparent encapsulation layer is solidified.

11. The method of claim 10, wherein after the phosphor tape is attached to the transparent encapsulation layer, the transparent encapsulation layer is heated and cured to firmly connect the transparent encapsulation layer with the phosphor tape.

12. The method of claim 8, wherein the phosphor tape is formed by coating, screen printing or tape casting.

13. The method of claim 8, wherein the phosphor tape is in a form of a roll when it is attached to the substrate.

14. The method of claim 9, wherein the phosphor tape is in a form of a roll when it is attached to the transparent encapsulation layer.

15. The method of claim 14, wherein the phosphor tape is applied to a top surface of the transparent encapsulation layer which is over the LED units, and a side surface of the transparent encapsulation layer which interconnects the top surface and the substrate.
